(19) United States
(12) Patent Application Publication
(10) Pub. No.: US 2026/0052838 A1
(43) Pub. Date: Feb. 19, 2026

(54) THIN-FILM TRANSISTOR, DISPLAY DEVICE INCLUDING THE SAME, AND ELECTRONIC DEVICE INCLUDING THE SAME

(71) Applicant: Samsung Display Co., LTD., Yongin-si (KR)

(72) Inventors: So Il YOON, Yongin-si (KR); Jun Hyun PARK, Yongin-si (KR); Young Wan SEO, Yongin-si (KR)

(73) Assignee: Samsung Display Co., LTD., Yongin-sI (KR)

(21) Appl. No.: 19/085,384

(22) Filed: Mar. 20, 2025

(30) Foreign Application Priority Data
Aug. 13, 2024 (KR) 10-2024-0108039

(51) Int. Cl. H10K 59/121; H10D 86/40

(52) U.S. Cl. CPC H10K 59/1213; H10D 86/421

(57) ABSTRACT

A thin-film transistor includes a substrate, an active pattern including a first area, a second area, and a channel area, a gate electrode overlapping the channel area, a gate insulating layer between the active pattern and the gate electrode, a first electrode connected to the first area, and a second electrode connected to the second area. The channel area includes first and second boundaries overlapping side surfaces of the gate electrode, and first and second side surfaces spaced apart from each other in a second direction. The active pattern includes curved portions recessed from the first and second side surfaces and spaced apart from each other by a first length. One of the curved portions is spaced apart from the first boundary by a second length, and another of the curved portions is spaced apart from the second boundary by the second length.

### CROSS-REFERENCE TO RELATED APPLICATION

This application claims priority to and benefits of Korean patent application No. 10-2024-0108039 under 35 U.S.C. § 119, filed on Aug. 13, 2024 in the Korean Intellectual Property Office, the entire contents of which are incorporated herein by reference.

### BACKGROUND

### 1. Technical Field

Embodiments relate to a thin-film transistor, a display device including the thin-film transistor, and an electronic device including the thin-film transistor.

### 2. Description of the Related Art

Recently, with increasing interest in information display, research and development on display devices have been actively conducted. For example, display devices may include thin-film transistors and capacitors that control pixel emission. Thin-film transistors may include a gate electrode, a first electrode, a second electrode, and an active pattern. The shape of the gate electrode may depend on the shape of the active pattern. In the case where the size of the gate electrode increases, it may be desirable to efficiently design a planar structure of a channel area of the active pattern within a design margin.

This background section is intended, in part, to provide useful context for understanding the technology. However, it may also include ideas, concepts, or recognitions that were not known or appreciated by those skilled in the pertinent art before the effective filing date of the subject matter disclosed herein.

### SUMMARY

Embodiments are directed to a thin-film transistor with improved performance. For example, the thin-film transistor employs a planar structure in which an active pattern includes curved portions, thereby reducing the surface area of a channel area and improving process variation.

Embodiments are directed to a display device including the thin-film transistor with improved performance.

An embodiment may provide a thin-film transistor included in a display device, including: a substrate; an active pattern disposed on the substrate, the active pattern including a first area, a second area, and a channel area between the first area and the second area; a gate electrode disposed on the active pattern, overlapping the channel area; a gate insulating layer disposed between the active pattern and the gate electrode; a first electrode disposed on the gate insulating layer, connected to the first area; and a second electrode disposed on the gate insulating layer, connected to the second area. The channel area may include a first boundary and a second boundary, that overlap side surfaces of the gate electrode and are spaced apart from each other in a first direction. The channel area may further include a first side surface and a second side surface, spaced apart from each other in a second direction intersecting with the first direction. The active pattern may include curved portions recessed from the first side surface and the second side surface of the channel area, respectively, in the second direction and in a direction opposite to the second direction. The curved portions may be spaced apart from each other by a first length in the first direction. One of the curved portions may be spaced apart from the first boundary by a second length in the first direction, and another of the curved portions may be spaced apart from the second boundary by the second length in a direction opposite to the first direction. The second length may be equal to or greater than the first length.

In an embodiment, the curved portions may include a first curved portion recessed from the first side surface in the second direction and a second curved portion recessed from the second side surface in a direction opposite to the second direction. The first curved portion may be spaced apart from the second side surface by a third length in the direction opposite to the second direction, and the second curved portion may be spaced apart from the first side surface by the third length in the second direction.

In an embodiment, the third length may be equal to the first length.

In an embodiment, a length of one of the first boundary or the second boundary in the second direction may be equal to a sum of a length of one of the curved portions in the second direction and the third length.

In an embodiment, the channel area may include a first portion adjacent to the first area, a second portion adjacent to the second area, and a third portion between the first portion and the second portion. The first portion may be spaced apart from the first curved portion by the first length in a direction opposite to the first direction, and the second portion may be spaced apart from the second curved portion by the first length in the first direction. The first portion and the second portion may each have a first width in the second direction. The first width may be equal to the third length.

In an embodiment, the third portion may partially surround the curved portions and may have a constant width.

In an embodiment, the first portion and the second portion may be spaced apart from a first imaginary line aligned with the second direction by an identical length. The first imaginary line may be positioned between the first curved portion and the second curved portion and may be spaced apart from each of the first curved portion and the second curved portion by an identical distance.

In an embodiment, the first portion and the second portion may overlap a second imaginary line aligned with the first direction. The third portion may include a dummy portion protruding in the second direction from an area adjacent to the second portion. The dummy portion, together with another part of the third portion, may form the second curved portion.

In an embodiment, the dummy portion may have a second width equal to the first length in the first direction and may have a length equal to a length of each of the first curved portion and the second curved portion in the second direction.

In an embodiment, the curved portions may further include a third curved portion recessed from the first side surface in the second direction. The third curved portion may be parallel to the first curved portion, with the second curved portion positioned therebetween.

In an embodiment, the channel area may include a first portion adjacent to the first area, a second portion adjacent to the second area, and a third portion between the first portion and the second portion. The first portion may be spaced apart from the first curved portion by the first length in a direction opposite to the first direction, and the second portion may be spaced apart from the third curved portion by the first length in the first direction. The first portion and the second portion may each have a first width in the second direction. The first width may be equal to the third length.

In an embodiment, the third portion may partially surround the curved portions and may have a constant width.

In an embodiment, the first portion and the second portion may be spaced apart from a first imaginary line aligned with the second direction by an identical length. The first imaginary line may be positioned between the first curved portion and the third curved portion and may be spaced apart from each of the first curved portion and the third curved portion by an identical distance.

In an embodiment, the third portion may include a dummy portion protruding in a direction opposite to the second direction from an area adjacent to the second portion. The dummy portion, together with another part of the third portion, may form the third curved portion.

In an embodiment, in case that the second length is greater than the first length, each of the curved portions may have a third width in the first direction. In case that the first length and the second length are equal to each other, each of the curved portions may have a fourth width greater than the third width in the first direction.

In an embodiment, the thin-film transistor may further include a plurality of insulating layers on the gate electrode. The first electrode and the second electrode may be disposed in a same layer on the insulating layers.

An embodiment may provide a display device, including: a display element; and a thin-film transistor that provides a driving signal to the display element. The thin-film transistor may include: a substrate; an active pattern disposed on the substrate, the active pattern including a first area, a second area, and a channel area between the first area and the second area; a gate electrode disposed on the active pattern, overlapping the channel area; a gate insulating layer disposed between the active pattern and the gate electrode; a first electrode disposed on the gate insulating layer, connected to the first area; and a second electrode disposed on the gate insulating layer, connected to the second area. The channel area may include a first boundary and a second boundary, that overlap side surfaces of the gate electrode and are spaced apart from each other in a first direction. The channel area may further include a first side surface and a second side surface, spaced apart from each other in a second direction intersecting with the first direction. The active pattern may include curved portions recessed from the first side surface and the second side surface of the channel area, respectively, in the second direction and in a direction opposite to the second direction. The curved portions may be spaced apart from each other by a first length in the first direction. One of the curved portions may be spaced apart from the first boundary by a second length in the first direction, and another of the curved portions may be spaced apart from the second boundary by the second length in a direction opposite to the first direction. The second length may be equal to or greater than the first length.

An embodiment may provide an electronic device, including: a processor that provides input image data; and a display device that displays an image based on the input image data, the display device including a display element and a thin-film transistor that provides a driving signal to the display element, wherein the thin-film transistor includes a substrate; an active pattern disposed on the substrate, the active pattern including a first area, a second area, and a channel area between the first area and the second area; a gate electrode disposed on the active pattern, overlapping the channel area; a gate insulating layer disposed between the active pattern and the gate electrode; a first electrode disposed on the gate insulating layer, connected to the first area; and a second electrode disposed on the gate insulating layer, connected to the second area, wherein the channel area includes a first boundary and a second boundary, which overlap side surfaces of the gate electrode and are spaced apart from each other in a first direction. The channel area may further include a first side surface and a second side surface, spaced apart from each other in a second direction intersecting with the first direction, wherein the active pattern includes curved portions recessed from the first side surface and the second side surface of the channel area, respectively, in the second direction and in a direction opposite to the second direction, wherein the curved portions are spaced apart from each other by a first length in the first direction, wherein one of the curved portions is spaced apart from the first boundary by a second length in the first direction, and another of the curved portions is spaced apart from the second boundary by the second length in a direction opposite to the first direction, and wherein the second length is equal to or greater than the first length.

In an embodiment, the electronic device may include, but is not limited to, at least one of a flat panel display, a curved display, a computer monitor, a medical monitor, a television, a billboard, an indoor light, an outdoor light, a signal light, a head-up display, a fully transparent display, a partially transparent display, a flexible display, a rollable display, a foldable display, a stretchable display, a laser printer, a telephone, a cellular phone, a video phone, a mobile phone, a smart pad, a tablet computer, a phablet, a personal digital assistant (PDA), a wearable device, a smartwatch, a navigation device for vehicles, a laptop computer, a digital camera, a camcorder, a viewfinder, a micro display, a three-dimensional (3D) display, a virtual reality display, an augmented reality display, a vehicle, a head-mounted display device, a video wall with multiple displays tiled together, a theater screen, a stadium screen, a phototherapy device, or a signboard.

### BRIEF DESCRIPTION OF THE DRAWINGS

The above and other aspects, features, and advantages of embodiments will be more apparent from the following description taken in conjunction with the accompanying drawings, in which:

FIG. 1 is a schematic block diagram illustrating an embodiment of a display device.

FIG. 2 is a schematic block diagram illustrating an embodiment of a sub-pixel in FIG. 1.

FIG. 3 is a schematic circuit diagram illustrating an embodiment of the sub-pixel in FIG. 2.

FIG. 4 is a schematic plan view illustrating an embodiment of a display panel in FIG. 1.

FIG. 5 is a schematic sectional view illustrating an embodiment of the display panel in FIG. 1.

FIG. 6 is a schematic sectional view taken along line I-I′ in FIG. 4.

FIGS. 7 to 14 are schematic plan views illustrating embodiments of a thin-film transistor.

FIG. 15 is a schematic block diagram illustrating an electronic device including a display device in an embodiment.

FIG. 16 is a schematic diagram illustrating an example where the electronic device in FIG. 15 is a smartphone.

FIG. 17 is a schematic diagram illustrating an example where the electronic device in FIG. 15 is a tablet computer.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art. Various embodiments do not have to be exclusive nor limit the disclosure. For example, specific shapes, configurations, and characteristics of an embodiment may be used or implemented in another embodiment.

In the drawings, sizes, thicknesses, ratios, and dimensions of the elements may be exaggerated for ease of description and for clarity. Like reference numbers and/or reference characters refer to like elements throughout.

As used herein, the singular forms “a,” “an,” and “the” are intended to include the plural forms as well, unless the context clearly indicates otherwise.

As used herein, the term “about” or “approximately” is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

In the specification and claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

The phrase “in a plan view” means viewing the object from the top, and the phrase “in a schematic cross-sectional view” means viewing a cross-section of which the object is vertically cut from the side. Hence, the expression “in a plan view” used herein may mean that an object is viewed in the third z direction from the top. The phrase “in a schematic cross-sectional view” means viewing a cross-section in the first x direction or the second y direction of which the object is vertically cut from the side. The third z direction also can be referred to as a “thickness direction.” It will be understood that when an element (or a layer, a region, a portion, or the like) is referred to as “formed on,” “being on,” “disposed on,” “connected to,” or “coupled to” another element in the specification, it can be directly formed on, disposed on, connected or coupled to another element mentioned above, or intervening elements may be disposed therebetween. It will be understood that the terms “connected to” or “coupled to”may include a physical or electrical connection or coupling.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

The phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

The term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” Although the terms “first,” “second,” etc. may be used herein to describe various types of elements, these elements should not be limited by these terms. These terms are used to distinguish one element from another element. For example, a first element may be referred to as a second element, and similarly, a second element may be referred to as a first element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element or feature's relationship to another element(s) or feature(s), as illustrated in the drawings. Spatially relative terms are intended to encompass different orientations of an apparatus in use, operation, and/or manufacture in addition to the orientation depicted in the drawings. For example, if the device in the drawings is turned upside down, elements described as “below” or “beneath” other elements or features would then be oriented “above” the other elements or features. Thus, the term “below” can encompass both an orientation of above and below. Furthermore, the device may be otherwise oriented (e.g., rotated 90 degrees or at other orientations), and, as such, the spatially relative descriptors used herein interpreted accordingly.

Herein, various embodiments will be described with reference to drawings that are schematic illustrations of idealized embodiments. Variations in the shapes of the illustrations may result, for example, from manufacturing techniques and/or tolerances and are to be expected. Therefore, embodiments disclosed herein should not be construed as limited to the illustrated shapes of regions but may include deviations in shapes resulting, for instance, from manufacturing processes. As such, the shapes illustrated in the drawings may not represent the actual shapes of regions of a device and are not intended to be limiting.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

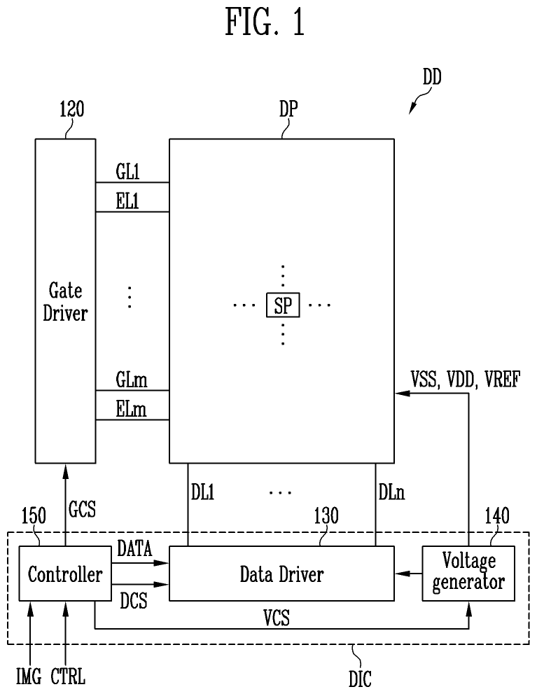

FIG. 1 is a schematic block diagram illustrating an embodiment of a display device DD.

Referring to FIG. 1, the display device DD may include a display panel DP, a gate driver 120, a data driver 130, a voltage generator 140, and a controller 150.

The display panel DP may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

Each of the sub-pixels SP may include at least one light emitting element that generates light. For example, each of the sub-pixels SP may generate light in a specific color such as red, green, blue, cyan, magenta, or yellow. Two or more sub-pixels among the sub-pixels SP may form a pixel PXL.

The gate driver 120 may be connected to sub-pixels SP arranged in a row direction through first to m-th gate lines GL1 to GLm. The gate driver 120 may output gate signals to the first to m-th gate lines GL1 to GLm in response to a gate control signal GCS. In embodiments, the gate control signal GCS may include a start signal instructing the start of each frame, a horizontal synchronization signal for outputting gate signals synchronized with a timing at which data signals are applied, and the like.

In embodiments, first to m-th emission control lines EL1 to ELm may be provided and connected to the sub-pixels SP in the row direction. The gate driver 120 may include an emission control driver that controls the first to m-th emission control lines EL1 to ELm. The emission control driver may operate under the control of the controller 150.

The gate driver 120 may be disposed on one side of the display panel DP. However, embodiments are not limited thereto. For example, the gate driver 120 may be divided into two or more drivers that are physically and/or logically distinguished from each other. The drivers may be disposed on a first side of the display panel DP and a second side of the display panel DP opposite the first side. As such, the gate driver 120 may be disposed around the display panel DP in various forms depending on the embodiments.

The data driver 130 may be connected to sub-pixels SP arranged in a column direction through the first to n-th data lines DL1 to DLn. The data driver 130 may receive image data DATA and a data control signal DCS from the controller 150. The data driver 130 may operate in response to the data control signal DCS. In embodiments, the data control signal DCS may include a source start pulse, a source shift clock, a source output enable signal, and the like.

The data driver 130 may apply data signals having grayscale voltages, corresponding to the image data DATA, to the first to n-th data lines DL1 to DLn using voltages from the voltage generator 140. In the case where a gate signal is applied to each of the first to m-th gate lines GL1 to GLm, data signals corresponding to the image data DATA may be applied to the data lines DL1 to DLn. Hence, the associated sub-pixels SP may generate light corresponding to the data signals, and an image may be displayed on the display panel DP.

In embodiments, the gate driver 120 and the data driver 130 may include complementary metal-oxide-semiconductor (CMOS) circuit elements.

The voltage generator 140 may operate in response to a voltage control signal VCS from the controller 150. The voltage generator 140 may generate multiple voltages and provide the generated voltages to components of the display device DD. For example, the voltage generator 140 may receive an input voltage from an external device outside the display device DD, adjust the received voltage, and regulate the adjusted voltage to generate multiple voltages.

The voltage generator 140 may generate a first power voltage VDD, a second power voltage VSS. The generated first power voltage VDD and second power voltage VSS may be supplied to the sub-pixels SP. The first power voltage VDD may have a relatively high voltage level. The second power voltage VSS may have a voltage level lower than the first power voltage VDD. In other embodiments, the first power voltage VDD or the second power voltage VSS may be provided by an external device outside the display device DD.

The voltage generator 140 may generate various voltages. For example, the voltage generator 140 may generate an initialization voltage applied to the sub-pixels SP. For example, during a sensing operation to detect electrical characteristics of transistors and/or light emitting elements of the sub-pixels SP, a reference voltage VREF may be applied to each of the first to n-th data lines DL1 to DLn. The voltage generator 140 may generate the reference voltage VREF.

The controller 150 may control overall operations of the display device DD. The controller 150 may receive input image data IMG and a control signal CTRL from an external device to control an operation of displaying the input image data IMG. The controller 150 may provide a gate control signal GCS, a data control signal DCS, and a voltage control signal VCS in response to the control signal CTRL.

The controller 150 may convert the input image data IMG to be suitable for the display device DD or the display panel DP before outputting image data DATA. In embodiments, the controller 150 may align the input image data IMG to be suitable for the sub-pixels SP on a row basis before outputting the image data DATA.

Two or more components of the data driver 130, the voltage generator 140, and the controller 150 may be mounted on a single integrated circuit. As illustrated in FIG. 1, the data driver 130, the voltage generator 140, and the controller 150 may be included in a driver integrated circuit DIC. The data driver 130, the voltage generator 140, and the controller 150 may be components that are functionally separated from each other in the single driver integrated circuit DIC. In other embodiments, at least one of the data driver 130, the voltage generator 140, and/or the controller 150 may be provided as a component separated from the driver integrated circuit DIC.

The controller 150 may control various operations of the display device DD. For example, the controller 150 may control components such as the data driver 130 and/or the voltage generator 140 to adjust data signals and the first and second power voltages VDD and VSS.

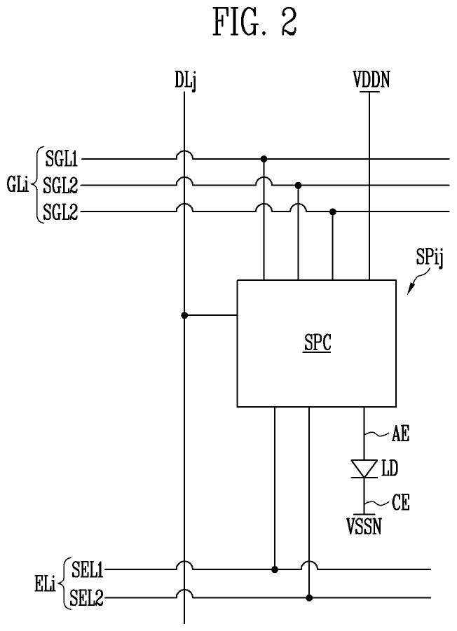

FIG. 2 is a schematic block diagram illustrating an embodiment of a sub-pixel SP in FIG. 1. In FIG. 2, a sub-pixel SPij is illustrated, disposed on an i-th row (where i is an integer between 1 and m, inclusive) and a j-th column (where j is an integer between 1 and n, inclusive) among the sub-pixels SP of FIG. 1.

Referring to FIG. 2, the sub-pixel SPij may include a sub-pixel circuit SPC and a light emitting element LD.

The light emitting element LD may be connected between a first power voltage node VDDN and a second power voltage node VSSN. The first power voltage node VDDN may transmit the first power voltage VDD of FIG. 1. The second power voltage node VSSN may transmit the second power voltage VSS of FIG. 1.

An anode electrode AE of the light emitting element LD may be connected to the first power voltage node VDDN through the sub-pixel circuit SPC. A cathode electrode CE of the light emitting element LD may be connected to the second power voltage node VSSN. For example, the anode electrode AE of the light emitting element LD may be connected to the first power voltage node VDDN through at least one transistor included in the sub-pixel circuit SPC. Accordingly, current may flow from the first power voltage node VDDN to the second power voltage node VSSN. The light emitting element LD may emit light corresponding to the amount of current.

The sub-pixel circuit SPC may be connected to an i-th gate line GLi among the first to m-th gate lines GL1 to GLm of FIG. 1, an i-th emission control line ELi among the first to m-th emission control lines EL1 to ELm of FIG. 1, and a j-th data line DLj among the first to n-th data lines DL1 to DLn of FIG. 1. The sub-pixel circuit SPC may control the light emitting element LD in response to signals received through the signal lines.

The sub-pixel circuit SPC may operate in response to a gate signal received through the i-th gate line GLi. The i-th gate line GLi may include one or more sub-gate lines. In embodiments, as illustrated in FIG. 2, the i-th gate line GLi may include first to third sub-gate lines SGL1 to SGL3. The sub-pixel circuit SPC may operate in response to gate signals received through the first to third sub-gate lines SGL1 to SGL3. As such, in the case where the i-th gate line GLi includes two or more sub-gate lines, the sub-pixel circuit SPC may operate in response to gate signals received through the corresponding sub-gate lines.

The sub-pixel circuit SPC may operate in response to an emission control signal received through the i-th emission control line ELi. The i-th emission control line ELi may include one or more sub-emission control lines. In embodiments, as illustrated in FIG. 2, the i-th emission control line ELi may include first and second sub-emission control lines SEL1 and SEL2. As such, in the case where the i-th emission control line ELi includes two or more sub-emission control lines, the sub-pixel circuit SPC may operate in response to emission control signals received through the corresponding sub-emission control lines.

The sub-pixel circuit SPC may receive a data signal through a j-th data line DLj. The sub-pixel circuit SPC may store a voltage corresponding to the data signal in response to at least one gate signal received through the first to third sub-gate lines SGL1 to SGL3. The sub-pixel circuit SPC may adjust current flowing from the first power voltage node VDDN to the second power voltage node VSSN through the light emitting element LD based on the stored voltage, in response to an emission control signal received through the i-th emission control line ELi. Therefore, the light emitting element LD may generate light with a luminance corresponding to the data signal.

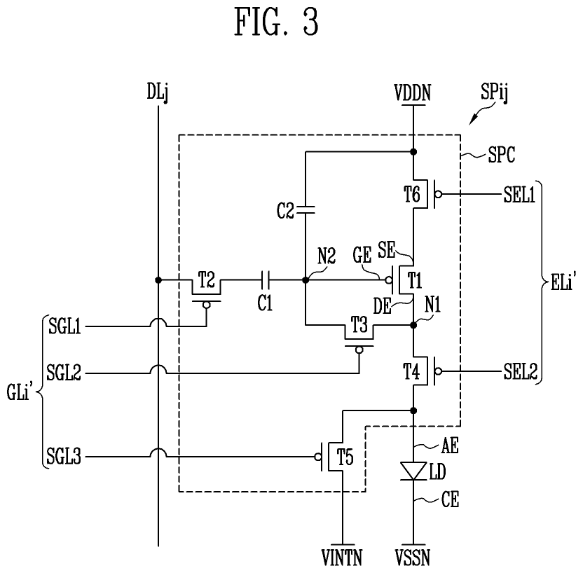

FIG. 3 is a schematic circuit diagram illustrating an embodiment of the sub-pixel SPij in FIG. 2.

Referring to FIG. 3, the sub-pixel circuit SPC of the sub-pixel SPij may be connected to an i-th gate line GLi′, an i-th emission control line ELi′, and a j-th data line DLj.

The sub-pixel circuit SPC may include first to sixth transistors T1 to T6, and first and second capacitors C1 and C2.

The first transistor T1 may be connected between the first power voltage node VDDN and a first node N1. A gate electrode GE of the first transistor T1 may be connected to a second node N2. Hence, the first transistor T1 may be turned on depending on a voltage level of the second node N2. The first transistor T1 may be referred to as a driving transistor.

The second transistor T2 may be connected between the j-th data line DLj and the second node N2. A gate electrode of the second transistor T2 may be connected to a first sub-gate line SGL1. Hence, the second transistor T2 may be turned on in response to a gate signal from the first sub-gate line SGL1. The second transistor T2 may be referred to as a switching transistor.

The third transistor T3 may be connected between the first node N1 and the second node N2. A gate electrode of the third transistor T3 may be connected to a second sub-gate line SGL2. Hence, the third transistor T3 may be turned on in response to a gate signal of the second sub-gate line SGL2.

The fourth transistor T4 may be connected between the first node N1 and the anode electrode AE of the light emitting element LD. A gate electrode of the fourth transistor T4 may be connected to the second sub-emission control line SEL2. Hence, the fourth transistor T4 may be turned on in response to an emission control signal from the second sub-emission control line SEL2.

The fifth transistor T5 may be connected between the anode electrode AE of the light emitting element LD and an initialization voltage node VINTN. The initialization voltage node VINTN may transmit an initialization voltage. In embodiments, the initialization voltage may be provided by the voltage generator 140 of FIG. 1. In other embodiments, the initialization voltage may be provided by an external device of the display device 100. A gate electrode of the fifth transistor T5 may be connected to a third sub-gate line SGL3. Hence, the fifth transistor T5 may be turned on in response to a gate signal from the third sub-gate line SGL3.

The sixth transistor T6 may be connected between the first power voltage node VDDN and the first transistor T1. A gate electrode of the sixth transistor T6 may be connected to the first sub-emission control line SEL1. Hence, the sixth transistor T6 may be turned on in response to an emission control signal of the first sub-emission control line SEL1.

The first capacitor C1 may be connected between the second transistor T2 and the second node N2. The second capacitor C2 may be connected between the first power voltage node VDDN and the second node N2.

As such, the sub-pixel circuit SPC may include the first to sixth transistors T1 to T6 and the first and second capacitors C1 and C2. However, the embodiments are not limited to this example. The sub-pixel circuit SPC may be implemented in various forms of circuits, each including multiple transistors and one or more capacitors. For example, the sub-pixel circuit SPC may include two transistors and one capacitor. Depending on embodiments of the sub-pixel circuit SPC, the number of sub-gate lines included in the i-th gate line GLi and the number of sub-emission control lines included in the i-th emission control line ELi may vary.

The first to sixth transistors T1 to T6 may be P-type transistors. Each of the first to sixth transistors T1 to T6 may be a thin-film transistor (TFT). However, embodiments are not limited to the foregoing. For example, at least one of the first to sixth transistors T1 to T6 may be replaced with an N-type transistor. In embodiments, the first to sixth transistors T1 to T6 may include an amorphous silicon semiconductor, a monocrystalline silicon semiconductor, a polycrystalline silicon semiconductor, an oxide semiconductor, or the like.

Each of the first to sixth transistors T1 to T6 may include a source electrode (or first electrode) SE, a drain electrode (or second electrode) DE, and a gate electrode GE.

The light emitting element LD may include an anode electrode AE, a cathode electrode CE, and an emission layer. The emission layer may be disposed between the anode electrode AE and the cathode electrode CE. In the case where emission control signals of the first and second sub-emission control lines SEL1 and SEL2 are enabled at a low level, after a data signal transmitted through the j-th data line DLj is reflected in the voltage of the second node N2, the fourth and sixth transistors T4 and T6 may be turned on. The first transistor T1 may be turned on in response to the voltage of the second node N2, enabling current to flow from the first power voltage node VDDN to the second power voltage node VSSN. The light emitting element LD may emit light corresponding to the amount of current.

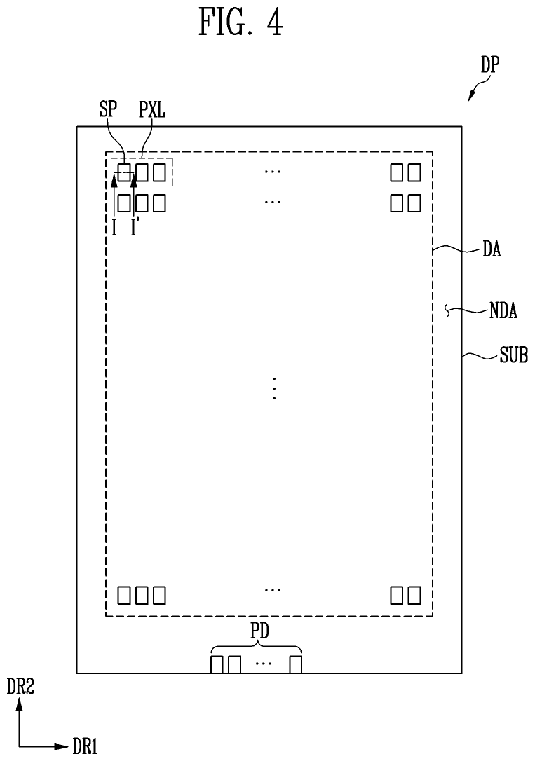

FIG. 4 is a schematic plan view illustrating an embodiment of the display panel DP in FIG. 1.

Referring to FIG. 4, an embodiment of the display panel DP depicted in FIG. 1 may include a display area DA and a non-display area NDA. The display panel DP may display an image through the display area DA. The non-display area NDA may be disposed around or surround the display area DA.

The display panel DP may include a substrate sub, sub-pixels SP, and pads PD.

The sub-pixels SP may be disposed in the display area DA on the substrate SUB. The sub-pixels SP may be arranged in a matrix pattern along a first direction DR1 and a second direction DR2 intersecting with the first direction DR1. However, embodiments are not limited to the example. For example, the sub-pixels SP may be arranged in a zigzag pattern in the first direction DR1 and the second direction DR2. For example, the sub-pixels SP may be arranged in a PENTILE™ pattern, which may align generally along the first direction DR1 and the second direction DR2. The first direction DR1 may correspond to a row direction, and the second direction DR2 may correspond to a column direction.

Two or more sub-pixels among the sub-pixels SP may form a pixel PXL. For example, three sub-pixels SP may combine to form a pixel PXL.

Components for controlling the sub-pixels SP may be disposed in the non-display area NDA on the substrate SUB. For example, lines, connected to the sub-pixels SP, such as the first to m-th gate lines GL1 to GLm and the first to n-th data lines DL1 to DLn of FIG. 1 may be disposed in the non-display area NDA.

At least one of the gate driver 120, the data driver 130, the voltage generator 140, and the controller 150 in FIG. 1 may be integrated into the non-display area NDA of the display panel DP. In embodiments, the gate driver 120 may be mounted on the display panel DP and positioned in the non-display area NDA. In other embodiments, the gate driver 120 may be implemented as an integrated circuit separate from the display panel DP.

The pads PD may be disposed in the non-display area NDA on the substrate SUB. The pads PD may be electrically connected to the sub-pixels SP through lines. For example, the pads PD may be connected to the sub-pixels SP through the first to n-th data lines DL1 to DLn.

The pads PD may interface the display panel DP with other components of the display device DD (see FIG. 1). In embodiments, the pads PD may provide voltages and signals required for operating the components included in the display panel DP from the driver integrated circuit DIC in FIG. 1. For example, the first to n-th data lines DL1 to DLn may be connected to the driver integrated circuit DIC through the pads PD. For example, the first and second power voltages VDD and VSS may be supplied from the driver integrated circuit DIC through the pads PD. For example, in the case where the gate driver 120 is mounted on the display panel DP, the gate control signal GCS may be transmitted from the driver integrated circuit DIC to the gate driver 120 through the pads PD.

In embodiments, a circuit board may be electrically connected to the pads PD using a conductive adhesive component, such as an anisotropic conductive film. The circuit board may be a flexible circuit board (FPCB) or a flexible film made of a flexible material. The driver integrated circuit DIC may be mounted on the circuit board and electrically connected to the pads PD.

In embodiments, the display area DA may have various shapes. The display area DA may have a closed-loop shape having linear and/or curved sides. For example, the display area DA may have shapes such as a polygon, a circle, a semicircle, or an ellipse.

In embodiments, the display panel DP may have a planar display surface. In embodiments, the display panel DP may have a display surface that is at least partially rounded. In embodiments, the display panel DP may be bendable, foldable, or rollable. The display panel DP and/or the substrate SUB may include materials having flexible properties.

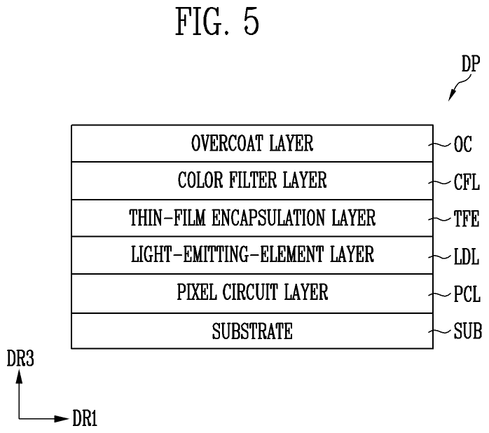

FIG. 5 is a schematic sectional view illustrating an embodiment of the display panel DP in FIG. 1.

Referring to FIG. 5, the display panel DP may include a substrate SUB, a pixel circuit layer PCL, a light-emitting element layer LDL, a thin-film encapsulation layer TFE, a color filter layer CFL, and an overcoat layer OC.

The substrate SUB may include a semiconductor substrate. For example, the substrate SUB may include a silicon bulk wafer, or an epitaxial wafer. The epitaxial wafer may include a crystalline material layer, i.e., an epitaxial layer, grown on a bulk substrate through an epitaxial process. The substrate SUB is not limited to bulk wafer or epitaxial wafer, but may be formed using various types of wafers, such as a polished wafer, an annealed wafer, and a silicon-on-insulator (SOI) wafer.

The pixel circuit layer PCL may be disposed on the substrate SUB and may include circuit elements of the sub-pixel circuit SPC (see FIG. 2) along with at least one insulating layer between the circuit elements. The circuit elements may include at least one transistor and signal lines connected to the at least one transistor.

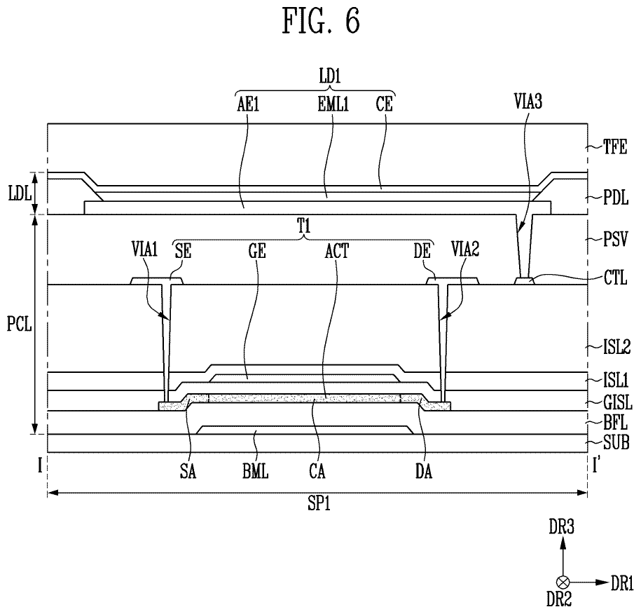

The light-emitting element layer LDL may include a light emitting element LD (see FIG. 2) and a pixel defining layer PDL (see FIG. 6). The light emitting element LD may be disposed in each of the sub-pixels SP. The light emitting element LD may include an anode electrode AE (see FIG. 2) connected to at least one transistor, an emission layer, and a cathode electrode CE (see FIG. 2).

The thin-film encapsulation layer TFE may be disposed on the light-emitting element layer LDL. The thin-film encapsulation layer TFE may cover the light-emitting element layer LDL to prevent oxygen and/or water or the like from penetrating into the light emitting element LD.

The color filter layer CFL may be disposed on the thin-film encapsulation layer TFE. The color filter layer CFL may selectively transmit light emitted from the light emitting elements LD in an image display direction (or frontal direction) of the display device DD, but is not limited thereto.

The overcoat layer OC may be disposed on the color filter layer CFL. The overcoat layer OC may cover underlying components, including the color filter layer CFL. The overcoat layer OC may protect the underlying components from foreign material such as dust.

FIG. 6 is a schematic sectional view taken along line I-I′ in FIG. 4.

FIG. 6 illustrates the first transistor T1 from the first to sixth transistors T1 to T6 shown in FIG. 3.

Referring to FIG. 6, the first transistor T1, in accordance with an embodiment, may include an active pattern ACT and a gate electrode GE insulated from the active pattern ACT. The first transistor T1 may include a source electrode SE and a drain electrode DE, which are connected to the active pattern ACT. The first transistor T1 may function as a driving thin-film transistor.

Hereinafter, a structure in which components included in the first transistor T1 are stacked will be described.

The buffer layer BFL may be disposed on the substrate SUB. The buffer layer BFL may reduce or block penetration of foreign substances, moisture, or external air from a lower portion of the substrate SUB and may provide a flat surface on the substrate SUB.

The buffer layer BFL may be an inorganic insulating layer including inorganic material. The buffer layer BFL may include at least one of silicon nitride (SiNₓ), silicon oxide (SiOₓ), and silicon oxynitride (SiOₓN_{y}), or may include at least one metal oxides such as aluminum oxide (AlOₓ). The buffer layer BFL may include silicon oxide (SiOₓ). The buffer layer BFL may have a single-layer or multilayer structure. In the case that the buffer layer BFL has a multilayer structure, the respective layers may be formed of the same material or different materials.

An active pattern ACT may be disposed on the buffer layer BFL. The active pattern ACT may include a source area SA, a drain area DA, and a channel area CA provided between the source area SA and the drain area DA. The source area SA and the drain area DA may be spaced apart from each other in the first direction DR1 or the second direction DR2 intersecting with the first direction DR1, with the channel area CA interposed therebetween. The source area SA and the drain area DA of the active pattern ACT may have conductivity by adjusting a carrier concentration in an oxide semiconductor.

The source area SA of the active pattern ACT may be connected to the source electrode SE through a first via hole VIA1. The first via hole VIA1 may pass through a gate insulating layer GISL and first and second insulating layers ISL1 and ISL2 to expose the source area SA of the active pattern ACT. The drain area DA of the active pattern ACT may be connected to the drain electrode DE through a second via hole VIA2. The second via hole VIA2 may pass through the gate insulating layer GISL and the first and second insulating layers ISL1 and ISL2 to expose the drain area DA of the active pattern ACT.

The gate insulating layer GISL may be disposed on the active pattern ACT to cover the active pattern ACT. The gate insulating layer GISL may have a single-layer or multilayer structure including inorganic insulating material. For example, the inorganic insulating material may include silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), zinc oxide (ZnO₂), or the like. Although FIG. 6 illustrates that the gate insulating layer GISL is formed on entire surfaces of the buffer layer BFL and the active pattern ACT, this configuration is not limited thereto. For example, the gate insulating layer GISL may be formed through an etching process to have the same width as the gate electrode GE.

### The Gate Electrode Ge May Be Disposed on the Gate

insulating layer GISL and may overlap the active pattern ACT. The gate electrode GE may be insulated from the active pattern ACT by the gate insulating layer GISL. The gate electrode GE may have a single-layer or multilayer structure including a copper (Cu) or a copper alloy, but is not limited thereto. For example, the gate electrode GE may include indium zinc oxide (InZnO), silver (Ag), zinc (Zn), magnesium (Mg), aluminum (Al), titanium (Ti), or the like.

The gate electrode GE may have a width smaller than a total width of the active pattern ACT in the first direction DR1 and equal to a width of the channel area CA of the active pattern ACT. Although FIG. 6 illustrates that the width of the gate electrode GE is substantially the same as that of the channel area CA of the active pattern ACT, this configuration is not limited thereto. For example, the gate electrode GE may have a width greater than the width of the channel area CA of the active pattern ACT in the first direction DR1.

The first insulating layer ISL1 may be disposed on the gate electrode GE. The first insulating layer ISL1 may cover the gate electrode GE. The first insulating layer ISL1 may have a single-layer or multilayer structure including inorganic insulating material. For example, the inorganic insulating material may include silicon oxide (SiOₓ), silicon nitride (SiNₓ), silicon oxynitride (SiOₓN_{y}), aluminum oxide (Al₂O₃), titanium oxide (TiO₂), or the like.

One or more insulating layers may be further disposed on the first insulating layer ISL1. Although FIG. 6 illustrates that the second insulating layer ISL2 is disposed on the first insulating layer ISL1, this configuration is not limited thereto. The second insulating layer ISL2 may include silicon oxide (SiOₓ), silicon nitride (SiNₓ), silicon oxynitride (SiOₓN_{y}), aluminum oxide (Al₂O₃), titanium oxide (TiO₂), or the like.

Conductive patterns may be disposed between the first insulating layer ISL1 and the second insulating layer ISL2. The conductive patterns may include electrodes at both ends of the first capacitor C1 and the second capacitor C2, as shown in FIG. 3. For example, the conductive patterns may further include the source electrode and the drain electrode of at least one of the second to sixth transistors T2 to T6, as shown in FIG. 3. Although the conductive patterns may include at least one of copper and a copper alloy, embodiments are not limited thereto. For example, the conductive patterns may include at least one of indium zinc oxide (InZnO), silver (Ag), zinc (Zn), magnesium (Mg), aluminum (Al), titanium (Ti), or the like. The active pattern (or the semiconductor layer) of at least one of the second to sixth transistors T2 to T6 may be further disposed between the first insulating layer ISL1 and one or more insulating layers.

The source electrode SE and the drain electrode DE, that are connected to the active pattern ACT, may be disposed on the second insulating layer ISL2. A conductive layer CTL may be disposed on the second insulating layer ISL2. For example, the source electrode SE, the drain electrode DE, and the conductive layer CTL may be disposed in the same layer. The conductive layer CTL may function as an electrode electrically connecting one of the transistors of FIG. 3 and the anode electrode AE of the light emitting element LD.

The source electrode SE, the drain electrode DE, and the conductive layer CTL may include a conductive material such as metal, or conductive oxide. For example, each of the source electrode SE, the drain electrode DE, and the conductive layer CTL may have a single-layer or multilayer structure including a metal such as molybdenum (Mo), aluminum (Al), chrome (Cr), gold (Au), titanium (Ti), nickel (Ni), neodymium (Nd), copper (Cu), or an alloy thereof.

The first transistor T1 including the active pattern ACT, the gate electrode GE, the source electrode SE, and the drain electrode DE, may be formed. In FIG. 6, the first transistor T1 is illustrated as a coplanar-type thin-film transistor with a top gate structure, but is not limited thereto. For example, the first transistor T1 may have a bottom gate structure. Although the second to sixth transistors T2 to T6 of FIG. 3 are not illustrated in FIG. 6, at least some of the second to sixth transistors T2 to T6 may have a structure similar to the first transistor T1.

In embodiments, a bottom conductive layer BML may be disposed between the substrate SUB and the buffer layer BFL. The bottom conductive layer BML may overlap the first transistor T1. For example, the bottom conductive layer BML may be disposed adjacent to the substrate SUB and beneath the first transistor T1. The bottom conductive layer BML may overlap the active pattern ACT of the first transistor T1. A constant voltage or signal may be applied to the bottom conductive layer BML.

The bottom conductive layer BML may include a metal or a conductive material. For example, the bottom conductive layer BML may have a single-layer or multilayer structure that includes molybdenum (Mo), aluminum (Al), copper (Cu), titanium (Ti), or the like. The bottom conductive layer BML may include a transparent conductive material. For example, the bottom conductive layer BML may include indium tin oxide (ITO), indium zinc oxide (IZO), zinc oxide (ZnO), indium oxide (In₂O₃), indium gallium oxide (IGO), aluminum zinc oxide (AZO), or the like.

A passivation layer PSV may be disposed over the source electrode SE, the drain electrode DE, and the conductive layer CTL of the first transistor T1. The passivation layer PSV may have a single-layer or multilayer structure that includes an inorganic insulating material. For example, the passivation layer PSV may have a single-layer structure that includes silicon oxide (SiOₓ), silicon nitride (SiNₓ), or silicon oxynitride (SiOₓN_{y}), or a multilayer structure in which two or more of silicon oxide (SiOₓ), silicon nitride (SiNₓ), and silicon oxynitride (SiOₓN_{y}) are alternately stacked.

A pixel defining layer PDL and a first light emitting element LD1, which includes a first anode electrode AE1, a first emission layer EML1, and a cathode electrode CE, may be disposed on the passivation layer PSV.

The first anode electrode AE1 may be formed on the pixel circuit layer PCL of the first sub-pixel SP1. For example, the first anode electrode AE1 may be formed on an insulating layer of the pixel circuit layer PCL, which has a flat surface, through a photolithography process using a mask. The first anode electrode AE1 may be disposed on the passivation layer PSV to overlap the conductive layer CTL and may be electrically connected to the conductive layer CTL through a third via hole VIA3 in the passivation layer PSV. For example, the first anode electrode AE1 may be electrically connected to the drain electrode of the fourth transistor T4 and the drain electrode of the fifth transistor T5, as described with reference to FIG. 3.

The first anode electrode AE1 may include a conductive material having reflectivity, enabling light emitted from the first emission layer EML1 to be reflected and directed toward the image display direction. For example, the conductive material may include a metal such as silver (Ag), magnesium (Mg), aluminum (Al), platinum (Pt), palladium (Pd), gold (Au), nickel (Ni), neodymium (Nd), iridium (Ir), chrome (Cr), titanium (Ti), or an alloy thereof.

The pixel defining layer PDL may be an organic insulating layer that includes an organic material. For example, the organic material may include acryl resin, epoxy resin, phenolic resin, polyamide resin, polyimide resin, or the like. In an embodiment, the pixel defining layer PDL may include a light absorbing material or be coated with a light absorbent, enabling the pixel defining layer PDL to absorb light introduced from the outside. For example, the pixel defining layer PDL may include a carbon-based black pigment, but is not limited thereto.

The first emission layer EML1 may be disposed on the first anode electrode AE1, which is exposed from the pixel defining layer PDL. The cathode electrode CE may be disposed on the first emission layer EML1. The cathode electrode CE may be a thin-film metal layer having a thickness that allows light emitted from the first emission layer EML1 to pass therethrough. For example, the cathode electrode CE may include a metallic material or a transparent conductive material with a relatively small thickness.

The thin-film encapsulation layer TFE may be formed over the entire surface of the cathode electrode CE. The thin-film encapsulation layer TFE may prevent foreign substances, moisture, or external air from penetrating into the first emission layer EML1 or the cathode electrode CE.

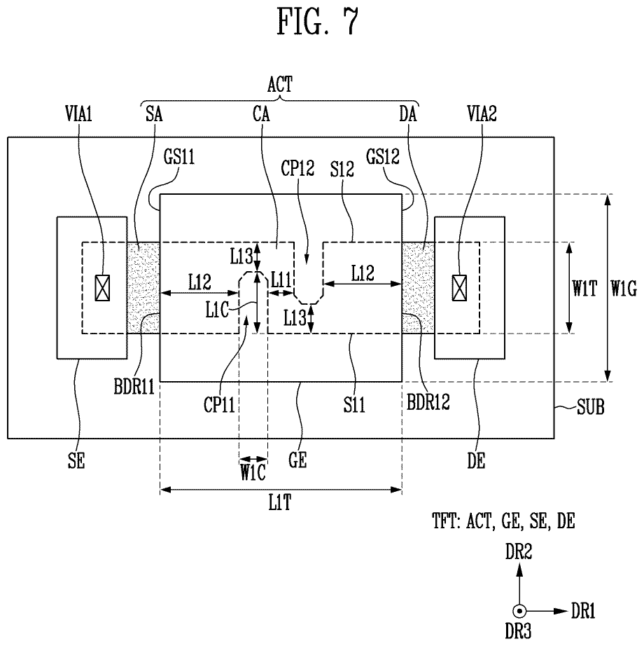

FIGS. 7 to 14 are schematic plan views illustrating embodiments of a thin-film transistor TFT. For convenience in explanation, the thin-film transistor TFT is assumed to be the first transistor T1 of FIG. 3. However, embodiments are not limited to the example. For example, the thin-film transistor TFT may be any one of the second to sixth transistors T2 to T6 of FIG. 3.

Referring to FIGS. 7 to 14, the thin-film transistor TFT in an embodiment may include a gate electrode GE, an active pattern (or semiconductor layer) ACT, a source electrode SE, and a drain electrode DE, which are provided on the substrate SUB.

The substrate SUB may include an insulating material such as glass, an organic polymer, or crystal. The substrate SUB may be made of a material having flexibility, allowing it to be bendable or foldable, and may have a single-layer or multi-layer structure. For example, the substrate SUB may include at least one of the following: polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, or cellulose acetate propionate. However, the material of the substrate SUB is not limited to the examples and may vary in other embodiments.

The active pattern ACT may be provided on the substrate SUB. The active pattern ACT may include a source area SA, a drain area DA, and a channel area CA provided between the source area SA and the drain area DA. The active pattern ACT may be a semiconductor pattern that includes polysilicon, amorphous silicon, an oxide semiconductor, etc. For example, the channel region CA may be an undoped semiconductor pattern and thus be an intrinsic semiconductor. Each of the source area SA and the drain area DA may be a semiconductor pattern doped with impurities.

The channel area CA of the active pattern ACT may overlap the gate electrode GE. The gate electrode GE may be formed of a conductive material, e.g., a metallic material. In an embodiment, the gate electrode GE may function as a doping prevention layer, preventing the active pattern ACT from being doped with impurities. As a result, the gate electrode GE may define the channel area CA of the active pattern ACT.

The source area SA of the active pattern ACT may overlap the source electrode (or first electrode) SE. The source electrode SE may be provided on the active pattern ACT and may cover at least a portion of the active pattern ACT. The source electrode SE may be connected to the source area SA through a first via hole VIA1 that passes through the gate insulating layer GISL (see FIG. 6) and the insulating layers ISL1 and ISL2 (see FIG. 6).

The drain area DA of the active pattern ACT may overlap the drain electrode (or second electrode) DE. The drain electrode DE may be provided on the active pattern ACT and may cover at least a portion of the active pattern ACT. The drain electrode DE may be spaced apart from the source electrode SE in the first direction DR1 by a certain distance. The drain electrode DE may be connected to the drain area DA through a second via hole VIA2 that passes through the gate insulating layer GISL and the insulating layers ISL1 and ISL2.

Referring to FIG. 7, the channel area CA of the active pattern ACT may have a first channel length L1T in the first direction DR1 and may have a first channel width W1T in the second direction DR2, which intersects with the first direction DR1. The gate electrode GE, overlapping the channel area CA of the active pattern ACT, may have the same first channel length L1T as the channel area CA in the first direction DR1. The gate electrode GE may have a width W1G greater than the first channel width W1T of the channel area CA in the second direction DR2. For example, the shape of the gate electrode GE may be determined based on the first channel length L1T of the channel area CA.

The channel area CA may include first and second boundaries BDR11 and BDR12, which overlap side surfaces GS11 and GS12 of the gate electrode GE that are spaced apart from each other in the first direction DR1. The channel area CA may include first and second side surfaces S11 and S12 spaced apart from each other in the second direction DR2. The channel area CA may be surrounded by the first and second boundaries BDR11 and BDR12 and the first and second side surfaces S11 and S12.

Referring to FIG. 7, the active pattern ACT may have an even number of curved portions in the channel area CA. In embodiments, the active pattern ACT may have curved portions CP11 and CP12, which are recessed from the first and second side surfaces S11 and S12 of the channel area CA in the second direction DR2 and a opposite direction to the second direction DR2, respectively. In the channel area CA, the curved portions CP11 and CP12 may be arranged in a zigzag pattern along the first direction DR1. The curved portions CP11 and CP12 may have an identical width W1C.

For example, the active pattern ACT may include a first curved portion CP11 recessed from the first side surface S11 in the second direction DR2 and a second curved portion CP12 recessed from the second side surface S12 in the opposite direction to the second direction DR2. The first curved portion CP11 and the second curved portion CP12 may be spaced apart from each other by a first length L11 in the first direction DR1. The first curved portion CP11 may be spaced apart from the first boundary BDR11 by a second length L12 in the first direction DR1. The second curved portion CP12 may be spaced apart from the second boundary BDR12 by the second length L12 in the opposite direction to the first direction DR1. The second length L12 may be equal to or greater than the first length L11 between the first and second curved portions CP11 and CP12. For example, in the case where the size of the gate electrode GE increases within the design margin, the second length L12 may be greater than the first length L11.

The first and second curved portions CP11 and CP12 may have a length L1C that is less than the first channel width W1T of the channel area CA in the second direction DR2. The first curved portion CP11 may be spaced apart from the second side surface S12 by a third length L13 in the opposite direction to the second direction DR2. The second curved portion CP12 may be spaced apart from the first side surface S11 by the third length L13 in the second direction DR2. The third length L13 may be equal to the first length L11 between the first and second curved portions CP11 and CP12.

The sum of the third length L13 and the length L1C of the first curved portion CP11 may be equal to the length W1T of each of the first and second boundaries in the second direction DR2. The sum of the third length L13 and the length of the second curved portion CP12 may also be equal to the length W1T of each of the first and second boundaries in the second direction DR2.

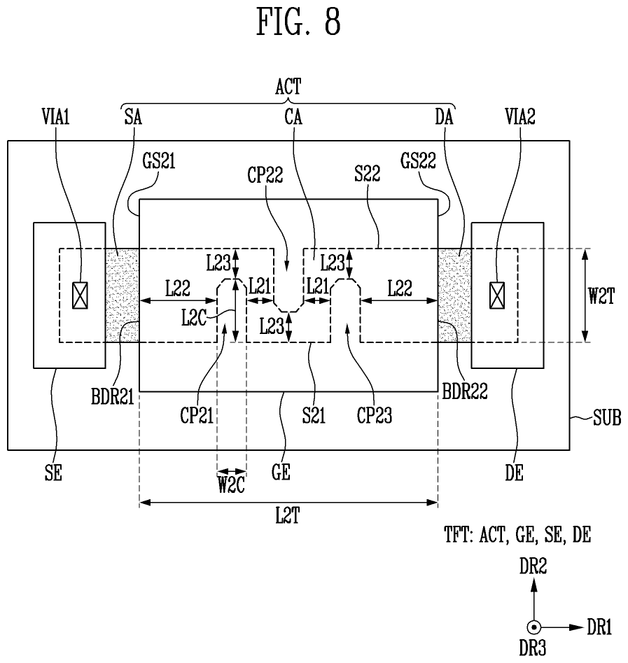

Referring to FIG. 8, the channel area CA of the active pattern ACT may have a first channel length L2T in the first direction DR1 and may have a first channel width W2T in the second direction DR2, which intersects with the first direction DR1. The gate electrode GE, overlapping the channel area CA of the active pattern ACT, may have the same first channel length L2T as the channel area CA in the first direction DR1. For example, the shape of the gate electrode GE may be determined based on the first channel length L2T of the channel area CA. The first channel length L2T in FIG. 8 may be greater than the first channel length L1T in FIG. 7. The first channel width W2T in FIG. 8 may be equal to the first channel width W1T in FIG. 7.

The channel area CA may include first and second boundaries BDR21 and BDR22, which overlap side surfaces GS21 and GS22 of the gate electrode GE that are spaced apart from each other in the first direction DR1. The channel area CA may include first and second side surfaces S21 and S22 spaced apart from each other in the second direction DR2. For example, the channel area CA may be surrounded by the first and second boundaries BDR21 and BDR22 and the first and second side surfaces S21 and S22.

Referring to FIG. 8, the active pattern ACT may have an odd number of curved portions in the channel area CA. In embodiments, the active pattern ACT may have curved portions CP21 to CP23, which are recessed from the first and second side surfaces S21 and S22 of the channel area CA in the second direction DR2 and the opposite direction to the second direction DR2, respectively. In the channel area CA, the curved portions CP21 to CP23 may be arranged in a zigzag pattern along the first direction DR1. The curved portions CP21 and CP22 may have an identical width W2C.

For example, the active pattern ACT may include first and third curved portions CP21 and CP23 recessed from the first side surface S21 in the second direction DR2, and a second curved portion CP22 recessed from the second side surface S22 in the opposite direction to the second direction DR2. The third curved portion CP23 may be disposed parallel to the first curve portion CP21, with the second curved portion CP22 provided therebetween.

The first to third curved portions CP21 to CP23 may be spaced apart from each other by a first length L21 in the first direction DR1. The first curved portion CP21 and the second curved portion CP22 may be spaced apart from each other by the first length L21 in the first direction DR1. The second curved portion CP22 and the third curved portion CP23 may also be spaced apart from each other by the first length L21 in the first direction DR1. The first curved portion CP21 may be spaced apart from the first boundary BDR21 by a second length L22 in the first direction DR1. The third curved portion CP23 may be spaced apart from the second boundary BDR22 by the second length L22 in the opposite direction to the first direction DR1. The second length L22 may be equal to or greater than the first length L21 between the first to third curved portions CP21 to CP23. For example, in the case where the size of the gate electrode GE increases within the design margin, the second length L22 may be greater than the first length L21.

The first to third curved portions CP21 to CP23 may have a length L2C that is less than the first channel width W2T of the channel area CA in the second direction DR2. Each of the first and third curved portions CP21 and CP23 may be spaced apart from the second side surface S22 by a third length L23 in the opposite direction to the second direction DR2. The second curved portion CP22 may be spaced apart from the first side surface S21 by the third length L23 in the second direction DR2. The third length L23 may be equal to the first length L21 between the first to third curved portions CP21 to CP23.

Furthermore, the sum of the third length L23 and the length L2C of the first curved portion CP21 may be equal to the length W2T of each of the first and second boundaries in the second direction DR2. The sum of the third length L23 and the length of the second curved portion CP22 may be equal to the length W2T of each of the first and second boundaries in the second direction DR2. The sum of the third length L23 and the length of the third curved portion CP23 may be equal to the length W2T of each of the first and second boundaries in the second direction DR2.

In this way, as the channel area CA of the active pattern ACT has a planar structure with curved portions, current may be induced to flow in a curved shape, increasing an effective channel length of the thin-film transistor TFT. As a result, a subthreshold swing value, which represents current variation below the threshold voltage of the thin-film transistor TFT, may be reduced, and a mobility value may be increased. However, in case that an excessive number of curved portions are formed in the channel area CA, the effective channel length may increase excessively, thus leading to an increase in power consumption. Taking into account the foregoing, the channel area CA of the active pattern ACT may be designed to have a second length L12 greater than the first length L11. For example, the channel area CA may not have a curved portion adjacent to the first and second boundaries BDR11 and BDR12. This design may prevent an excessive increase in the effective channel length, thereby avoiding excessive or unnecessary increases in power consumption.

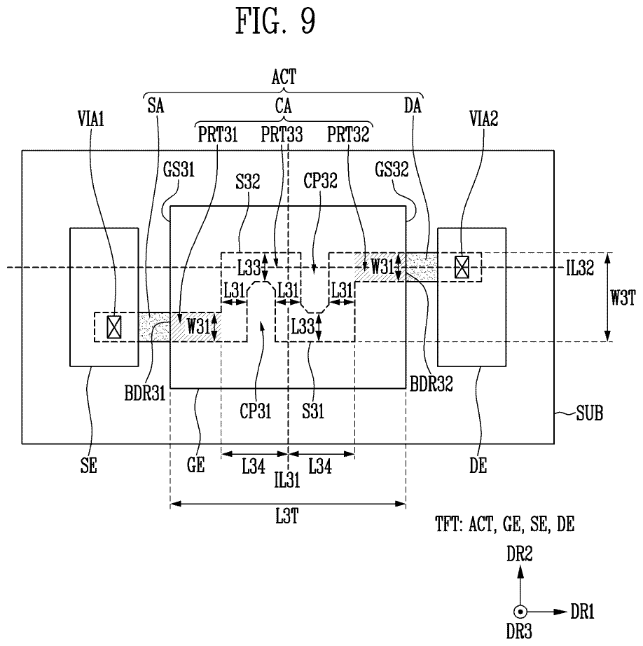

Referring to FIG. 9, an embodiment is illustrated in which the active pattern ACT may have an even number of curved portions in the channel area CA. In embodiments, the channel area CA of the active pattern ACT may include first and second boundaries BDR31 and BDR32, each of which has a first width W31. The channel area CA of the active pattern ACT may have a length L3T in the first direction DR1 and may have a width W3T in the second direction DR2.

The channel area CA may include the first and second boundaries BDR31 and BDR32, which overlap side surfaces GS31 and GS32 of the gate electrode GE spaced apart from each other in the first direction DR1. The first and second boundaries BDR31 and BDR32 of the channel area CA may have a first width W31. The first width W31 of the first and second boundaries BDR31 and BDR32 may be less than the width W3T defined between first and second side surfaces S31 and S32 of the channel area CA. Any one of the first and second boundaries BDR31 and BDR32 may overlap a second imaginary line IL32 aligned in the first direction DR1.

The active pattern ACT may have curved portions CP31 and CP32, which are recessed from the first and second side surfaces S31 and S32 of the channel area CA in the second direction DR2 and the opposite direction to the second direction DR2, respectively. In the channel area CA, the curved portions CP31 and CP32 may be arranged in a zigzag pattern along the first direction DR1.

For example, the active pattern ACT may include a first curved portion CP31 recessed from the first side surface S31 in the second direction DR2 and a second curved portion CP32 recessed from the second side surface S32 in the opposite direction to the second direction DR2. The first curved portion CP31 and the second curved portion CP32 may be spaced apart from each other by a first length L31 in the first direction DR1. The first curved portion CP31 may be spaced apart from a first portion PRT31, which includes the first boundary BDR31, by the first length L31 in the first direction DR1. The second curved portion CP32 may be spaced apart from a second portion PRT32, which includes the second boundary BDR32, by the first length L31 in a opposite direction to the first direction DR1.

The first curved portion CP31 may be spaced apart from the second side surface S32 by a third length L33 in the opposite direction to the second direction DR2. The second curved portion CP32 may be spaced apart from the first side surface S31 by the third length L33 in the second direction DR2. The third length L33 may be equal to the first length L31 between the first and second curved portions CP31 and CP32. Furthermore, the third length L33 may be equal to the first width W31 of each of the first and second boundaries BDR31 and BDR32.

In embodiments, the channel area CA may include a first portion PRT31 adjacent to a first area SA, a second portion PRT32 adjacent to a second area DA, and a third portion PRT33 between the first and second portions PRT31 and PRT32.

The first portion PRT31 may be spaced apart from the first curved portion CP31 by the first length L31 in the opposite direction to the first direction DR1. The first portion PRT31 may refer to an area defined between the first boundary BDR31 and the third portion PRT33. The second portion PRT32 may be spaced apart from the second curved portion CP32 by the first length L31 in the first direction DR1. The second portion PRT32 may refer to an area defined between the second boundary BDR32 and the third portion PRT33. Any one of the first and second portions PRT31 and PRT32 may overlap the second imaginary line IL32 aligned in the first direction DR1.

Furthermore, the first and second portions PRT31 and PRT32 may be spaced apart from a first imaginary line IL31, aligned with the second direction DR2, by an identical length L34. The first portion PRT31 may be spaced apart from the first imaginary line IL31 by the fourth length L34 in the opposite direction to the first direction DR1. The second portion PRT32 may be spaced apart from the first imaginary line IL31 by the fourth length L34 in the first direction DR1. The first imaginary line IL31 may be a single line that is disposed between the first and second curved portions CP31 and CP32 and spaced from each of the first and second curved portions CP31 and CP32 at an equal distance.

The third portion PRT33 may partially surround the first and second curved portions CP31 and CP32 and may have a constant width L33. The width L33 of the third portion PRT33 may be equal to the first width W31 of the first and second portions PRT31 and PRT32. The width L33 of the third portion PRT33 may be equal to the first length L31 by which the first curved portion CP31 and the first portion PRT31 are spaced apart from each other in the first direction DR1. The width L33 of the third portion PRT33 may also be equal to the first length L31 by which the second curved portion CP32 and the second portion PRT32 are spaced apart from each other in the first direction DR1.

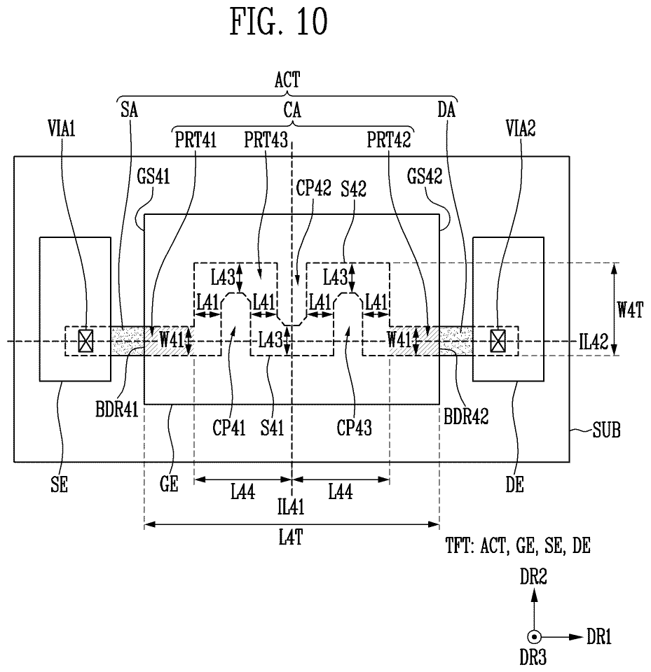

Referring to FIG. 10, an embodiment is illustrated in which the active pattern ACT may have an odd number of curved portions in the channel area CA. In embodiments, the channel area CA of the active pattern ACT may include first and second boundaries BDR41 and BDR42, each of which has a first width W41. The channel area CA of the active pattern ACT may have a length L4T in the first direction DR1 and may have a width W4T in the second direction DR2.

The channel area CA may include first and second boundaries BDR41 and BDR42, which overlap side surfaces GS41 and GS42 of the gate electrode GE that are spaced apart from each other in the first direction DR1. The first and second boundaries BDR41 and BDR42 of the channel area CA may have a first width W41. The first width W41 of the first and second boundaries BDR41 and BDR42 may be less than the width W4T defined between first and second side surfaces S41 and S42 of the channel area CA. The first and second boundaries BDR41 and BDR42 may overlap a second imaginary line IL42 aligned in the first direction DR1.

The active pattern ACT may have curved portions CP41 to CP43, which are recessed from the first and second side surfaces S41 and S42 of the channel area CA in the second direction DR2 and the opposite direction to the second direction DR2, respectively. In the channel area CA, the curved portions CP41 to CP43 may be arranged in a zigzag pattern along the first direction DR1.

For example, the active pattern ACT may include first and third curved portions CP41 and CP43 recessed from the first side surface S41 in the second direction DR2, and a second curved portion CP42 recessed from the second side surface S42 in the opposite direction to the second direction DR2. The third curved portion CP43 may be disposed parallel to the first curve portion CP41, with the second curved portion CP42 provided therebetween.

The first to third curved portions CP41 to CP43 may be spaced apart from each other by a first length L41 in the first direction DR1. The first curved portion CP41 may be spaced apart from a first portion PRT41, which includes the first boundary BDR41 by the first length L41 in the first direction DR1. The second curved portion CP42 may be spaced apart from first curved portion CP41 by the first length L41 in the first direction DR1. The third curved portion CP43 may be spaced apart from a second portion PRT42, which includes the second boundary BDR42, by the first length L41 in a opposite direction to the first direction DR1. The third curved portion CP43 may be spaced apart from second curved portion CP42 by the first length L41 in the first direction DR1.

Each of the first and third curved portions CP41 and CP43 may be spaced apart from the second side surface S42 by a third length L43 in the opposite direction to the second direction DR2. The second curved portion CP42 may be spaced apart from the first side surface S41 by the third length L43 in the second direction DR2. The third length L43 may be equal to the first length L41 between the first to third curved portions CP41 to CP43. Furthermore, the third length L43 may be equal to the first width W41 of each of the first and second boundaries BDR41 and BDR42.

In embodiments, the channel area CA may include a first portion PRT41 adjacent to a first area SA, a second portion PRT42 adjacent to a second area DA, and a third portion PRT43 between the first and second portions PRT41 and PRT42.

The first portion PRT41 may be spaced apart from the first curved portion CP41 by a first length L41 in the opposite direction to the first direction DR1. The first portion PRT41 may refer to an area defined between the first boundary BDR41 and the third portion PRT43. The second portion PRT42 may be spaced apart from the third curved portion CP43 by the first length L41 in the first direction DR1. The second portion PRT42 may refer to an area defined between the second boundary BDR42 and the third portion PRT43. The first and second portions PRT41 and PRT42 may overlap the second imaginary line IL42 aligned in the first direction DR1.

Furthermore, the first and second portions PRT41 and PRT42 may be spaced apart from a first imaginary line IL41, aligned with the second direction DR2, by an identical length L44. The first portion PRT41 may be spaced apart from the first imaginary line IL41 by the fourth length L44 in the opposite direction to the first direction DR1. The second portion PRT42 may be spaced apart from the first imaginary line IL41 by the fourth length L44 in the first direction DR1. The first imaginary line IL41 may be a single line that is disposed between the first and third curved portions CP41 and CP43 and spaced at an equal distance from each of the first and third curved portions CP41 and CP43. The first imaginary line IL41 may overlap the second curved portion CP42.

The third portion PRT43 may partially surround the first to third curved portions CP41 to CP43 and may have a constant width L43. The width L43 of the third portion PRT43 may be equal to the first width W41 of each of the first and second portions PRT41 and PRT42. The width L43 of the third portion PRT43 may be equal to the first length L41 by which the first curved portion CP41 and the first portion PRT41 are spaced apart from each other in the first direction DR1. The width L43 of the third portion PRT43 may also be equal to the first length L41 by which the third curved portion CP43 and the second portion PRT42 are spaced apart from each other in the first direction DR1. The width L43 of the third portion PRT43 may be equal to the first length L41 between the first to third curved portions CP41 to CP43.

In this way, the channel area CA of the active pattern ACT may employ a planar structure with the first and second portions, where the width of the channel area is reduced, instead of forming curved portions adjacent to the first and second boundaries BDR11 and BDR12. As a result, the capacitance of the active pattern ACT may be reduced, thereby preventing excessive power consumption. For example, since the active pattern ACT has a planar structure with a reduced width of the channel area CA, the characteristics of the thin-film transistor TFT may be further enhanced.

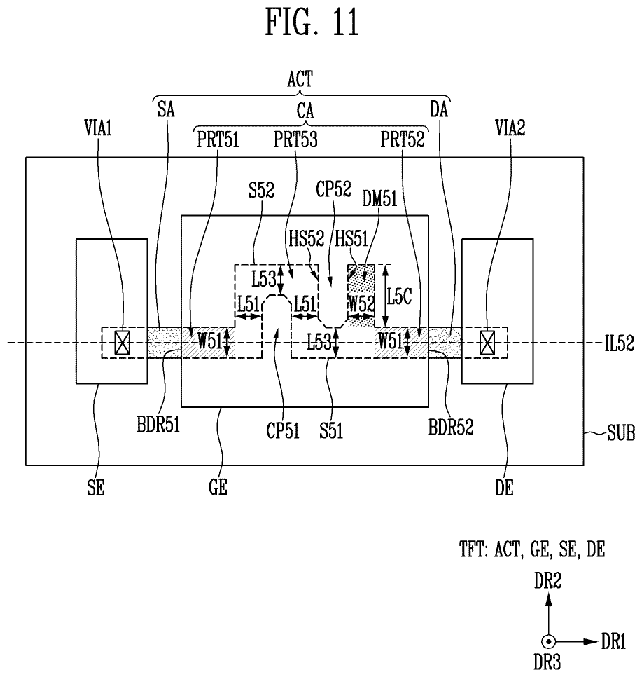

Referring to FIG. 11, an embodiment is illustrated in which the active pattern ACT may have an even number of curved portions in the channel area CA. In embodiments, the active pattern ACT may include a dummy portion DM51 protruding from the channel area CA in the second direction DR2.

The channel area CA may include first and second portions PRT51 and PRT52 that overlap a second imaginary line IL52 aligned with the first direction DR1. The channel area CA of the active pattern ACT may include a third portion PRT53 between the first and second portions PRT51 and PRT52.

For example, the third portion PRT53 may include a dummy portion DM51 protruding from an area adjacent to the second portion PRT52 in the second direction DR2. The protruding dummy portion DM51 may not overlap the second imaginary line IL52. The dummy portion DM51, along with another part of the third portion PRT53, may define a second curved portion CP52 adjacent to the second portion PRT52.

The dummy portion DM51 may have a second width W52 equal to a first length L51 in the first direction DR1 and may have a length L5C equal to the length of the first and second curved portions CP51 and CP52 in the second direction DR2.

For example, the active pattern ACT may include a first curved portion CP51 recessed from a first side surface S51 in the second direction DR2 and a second curved portion CP52 recessed from a second side surface S52 in the opposite direction to the second direction DR2. The first curved portion CP51 and the second curved portion CP52 may be spaced apart from each other by the first length L51 in the first direction DR1. The first curved portion CP51 may be spaced apart from the first portion PRT51, which includes a first boundary BDR51, by the first length L51 in the first direction DR1. The second curved portion CP52 may be spaced apart from the second portion PRT52, which includes a second boundary BDR52, by the second width W52 of the dummy portion DM51 in the opposite direction to the first direction DR1. The first length L51 may be equal to the second width W52.

The first curved portion CP51 may be spaced apart from the second side surface S52 by a third length L53 in the opposite direction to the second direction DR2. The second curved portion CP52 may be spaced apart from the first side surface S51 by the third length L53 in the second direction DR2. The third length L53 may be equal to the first length L51 between the first and second curved portions CP51 and CP52. The third length L53 may be equal to a first width W51 of each of the first and second boundaries BDR51 and BDR52. The third length L53 may be equal to the second width W52 of the dummy portion DM51.

In embodiments, the third portion PRT53 may partially surround the first and second curved portions CP51 and CP52. For example, the third portion PRT53 may surround the first curved portion CP51 except for one side extending from the first curved portion CP51 along the first side surface S51 in the first direction DR1. The third portion PRT53 may surround the second curved portion CP52 except for one side extending from the second curved portion CP52 along the second side surface S52 in the first direction DR1. A first surface HS51 of the second curved portion CP52 may contact the dummy portion DM51 of the third portion PRT53. The second curved portion CP52 and the dummy portion DM51 may share and contact the first surface HS51.

As the active pattern ACT has the dummy portion DM51 in an area of the channel area CA adjacent to the first and second boundaries BDR51 and BDR52, process variation may be reduced or minimized. For example, as the dummy portion DM51 is formed on the first surface HS51 of the second curved portion CP52, both the first surface HS51 and a second surface HS52 of the second curved portion CP52 may be uniformly surrounded by the third portion PRT53. Accordingly, during a process of patterning the active pattern ACT, the first surface HS51 and the second surface HS52 of the second curved portion CP52 may be patterned to the same degree. For example, process variation in the active pattern ACT may be reduced by using the dummy portion DM51 to make a peripheral area of the second curved portion CP52 uniform.

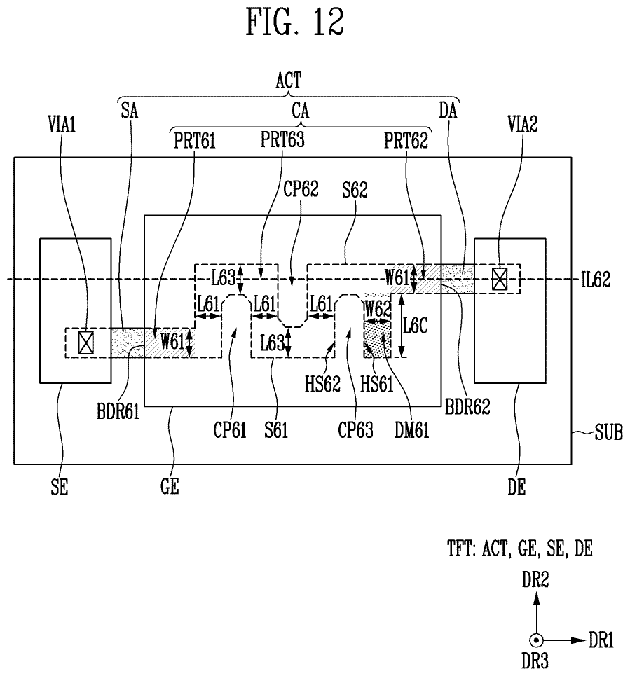

Referring to FIG. 12, an embodiment is illustrated in which the active pattern ACT may have an odd number of curved portions in the channel area CA. In embodiments, the active pattern ACT may include a dummy portion DM61 protruding from the channel area CA in the opposite direction to the second direction DR2.

The channel area CA may include a first portion PRT61 that does not overlap a second imaginary line IL62 aligned with the first direction DR1, and a second portion PRT62 that overlaps the second imaginary line IL62. The channel area CA of the active pattern ACT may include a third portion PRT63 between the first and second portions PRT61 and PRT62.

The third portion PRT63 may include a dummy portion DM61 protruding from an area adjacent to the second portion PRT62 in the opposite direction to the second direction DR2. The second portion PRT62 may overlap the second imaginary line IL62. The protruding dummy portion DM61 may not overlap the second imaginary line IL62. The dummy portion DM61, along with another part of the third portion PRT63, may define a third curved portion CP63 adjacent to the second portion PRT62.

The dummy portion DM61 may have a second width W62 equal to a first length L61 in the first direction DR1 and may have a length L6C equal to the length of the first to third curved portions CP61 to CP63 in the second direction DR2.

For example, the active pattern ACT may include first and third curved portions CP61 and CP63 recessed from a first side surface S61 in the second direction DR2, and a second curved portion CP62 recessed from a second side surface S62 in the opposite direction to the second direction DR2. The first to third curved portions CP61 to CP63 may be spaced apart from each other by a first length L61 in the first direction DR1. The first curved portion CP61 may be spaced apart from a first portion PRT61, which includes a first boundary BDR61, by the first length L61 in the first direction DR1. The third curved portion CP63 may be spaced apart from the second portion PRT62, which includes a second boundary BDR62, by the second width W62 of the dummy portion DM61 in the opposite direction to the first direction DR1. The first length L61 may be equal to the second width W62.

Each of the first and third curved portions CP61 and CP63 may be spaced apart from the second side surface S62 by a third length L63 in the opposite direction to the second direction DR2. The second curved portion CP62 may be spaced apart from the first side surface S61 by the third length L63 in the second direction DR2. The third length L63 may be equal to the first length L61 between the first to third curved portions CP61 to CP63. The third length L63 may be equal to a first width W61 of each of the first and second boundaries BDR61 and BDR62. The third length L63 may also be equal to the second width W62 of the dummy portion DM61.

In embodiments, the third portion PRT63 may partially surround the first to third curved portions CP61 to CP63. For example, the third portion PRT63 may surround the first curved portion CP61 except for one side extending from the first side surface S61 in the first direction DR1. The third portion PRT63 may surround the second curved portion CP62 except for one side extending from the second curved portion CP62 along the second side surface S62 in the first direction DR1. The third portion PRT63 may surround the third curved portion CP63 except for one side extending from the third curved portion CP63 along the first side surface S61 in the first direction DR1. A first surface HS61 of the third curved portion CP63 may contact the dummy portion DM61 of the third portion PRT63. The third curved portion CP63 and the dummy portion DM61 may share and contact the first surface HS61.

As the active pattern ACT has the dummy portion DM61 in an area of the channel area CA adjacent to the first and second boundaries BDR61 and BDR62, process variation may be reduced or minimized. For example, as the dummy portion DM61 is formed on the first surface HS61 of the third curved portion CP63, both the first surface HS61 and a second surface HS62 of the third curved portion CP63 may be uniformly surrounded by the third portion PRT63. Accordingly, during a process of patterning the active pattern ACT, the first surface HS61 and the second surface HS62 of the third curved portion CP63 may be patterned to the same degree. For example, process variation in the active pattern ACT may be reduced by using the dummy portion DM61 to make a peripheral area of the third curved portion CP63 uniform.

In this way, as the channel area CA of the active pattern ACT employs a planar structure with a separate dummy portion DM61 provided in an area adjacent to the first and second boundaries BDR61 and BDR62, process variation in the active pattern ACT may be reduced or minimized, thereby further enhancing the characteristics of the thin-film transistor TFT.

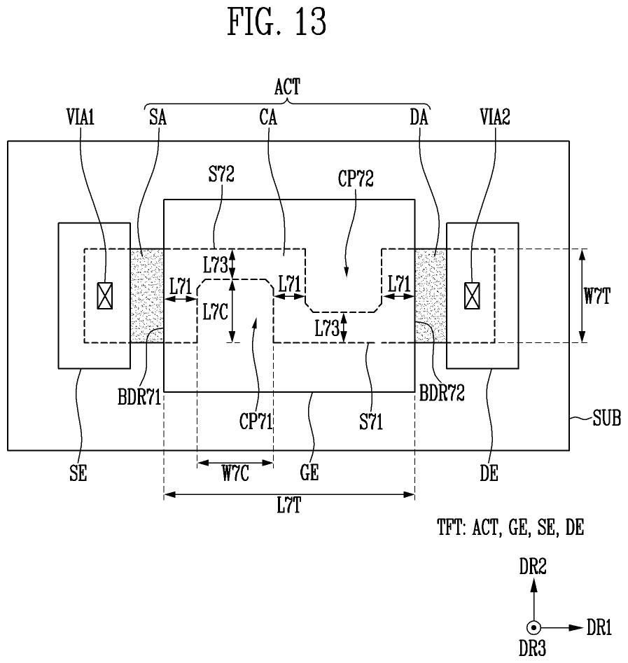

Referring to FIG. 13, an embodiment is illustrated in which the active pattern ACT may have an even number of curved portions in the channel area CA. In embodiments, the channel area CA of the active pattern ACT may have a first channel length L7T in the first direction DR1 and may have a first channel width W7T in the second direction DR2, which intersects with the first direction DR1.

For example, the active pattern ACT may include a first curved portion CP71 recessed from the first side surface S71 in the second direction DR2 and a second curved portion CP72 recessed from the second side surface S72 in the opposite direction to the second direction DR2. The first curved portion CP71 and the second curved portion CP72 may be spaced apart from each other by a first length L71 in the first direction DR1. The first curved portion CP11 may be spaced apart from a first boundary BDR71 by the first length L71 in the first direction DR1. The second curved portion CP72 may be spaced apart from a second boundary BDR72 by the first length L71 in the opposite direction to the first direction DR1.

The first and second curved portions CP71 and CP72 may have a length L7C that is less than the first channel width W7T of the channel area CA in the second direction DR2. The first curved portion CP71 may be spaced apart from the second side surface S72 by a third length L73 in the opposite direction to the second direction DR2. The second curved portion CP72 may be spaced apart from the first side surface S71 by a third length L73 in the second direction DR2. The third length L73 may be equal to the first length L71.

The first and second curved portions CP71 and CP72 may have an identical width W7C. The length of a remaining portion of each of the first and second curved portions CP71 and CP72, excluding fixed areas, may be equal to the width W7C. The fixed areas may refer to regions that are respectively defined by the first length L71 from the first and second boundaries BDR71 and BDR72, and a region that is defined between the first and second curved portions CP71 and CP72 by the first length L71. For example, in the case where the size of the gate electrode GE is increased with the design margin, the first length L71 may remain fixed, and the width W7C of each of the first and second curved portions CP71 and CP72 may increase. In the channel area CA of the active pattern ACT, as the first channel length L7T increases, the width W7C of each of the first and second curved portions CP71 and CP72 may also increase.

Although FIGS. 7, 9, 11, and 13 illustrate the active pattern ACT as including two curved portions in the channel area CA, the embodiments are not limited thereto. For example, the active pattern ACT may further include two additional curved portions between the first and second curved portions.

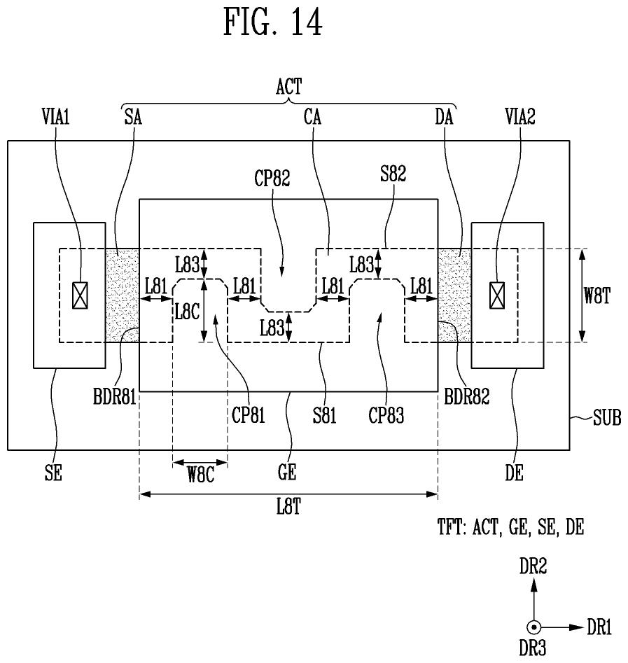

Referring to FIG. 14, an embodiment is illustrated in which the active pattern ACT may have an odd number of curved portions in the channel area CA. In embodiments, the channel area CA of the active pattern ACT may have a first channel length L8T in the first direction DR1 and may have a first channel width W8T in the second direction DR2, which intersects with the first direction DR1.

For example, the active pattern ACT may include first and third curved portions CP81 and CP83 recessed from a first side surface S81 in the second direction DR2 and a second curved portion CP82 recessed from a second side surface S82 in the opposite direction to the second direction DR2. The first to third curved portions CP81 to CP83 may be spaced apart from each other by a first length L81 in the first direction DR1. The first curved portion CP81 may be spaced apart from a first boundary BDR81 by the first length L81 in the first direction DR1. The second curved portion CP82 may be spaced apart from a second boundary BDR82 by the first length L81 in the opposite direction to the first direction DR1.

The first and second curved portions CP81 and CP82 may have a length L8C that is less than the first channel width W8T of the channel area CA in the second direction DR2. Each of the first and third curved portions CP81 and CP83 may be spaced apart from the second side surface S82 by a third length L83 in the opposite direction to the second direction DR2. The second curved portion CP82 may be spaced apart from the first side surface S81 by a third length L83 in the second direction DR2. The third length L83 may be equal to the first length L81.

The first to third curved portions CP81 to CP83 may have an identical width W8C. The length of a remaining portion of each of the first to third curved portions CP81 to CP83, excluding fixed areas, may be equal to the width W8C. The fixed areas may refer to regions that are respectively defined by the first length L81 from the first and second boundaries BDR81 and BDR82, and regions each of which are defined by the first length L81 between the first to third curved portions CP81 to CP83. For example, in the case where the size of the gate electrode GE is increased with the design margin, the first length L81 may remain fixed, and the width W8C of each of the first to third curved portions CP81 and CP83 may increase. In the channel area CA of the active pattern ACT, as the first channel length L8T increases, the width W8C of each of the first to third curved portions CP81 to CP83 may also increase.

Although FIGS. 8, 10, 12, and 14 illustrate the active pattern ACT as including three curved portions in the channel area CA, the embodiments are not limited thereto. For example, the active pattern ACT may further include two additional curved portions in addition to the second curved portion between the first and third curved portions.

In this way, the channel area CA of the active pattern ACT may have a planar structure in which the curved portions have increased widths, instead of forming curved portions adjacent to the first and second boundaries BDR11 and BDR12. As a result, the effective channel length of the thin-film transistor TFT may be increased, while the capacitance of the active pattern ACT is reduced, thereby further enhancing the characteristics of the thin-film transistor TFT.

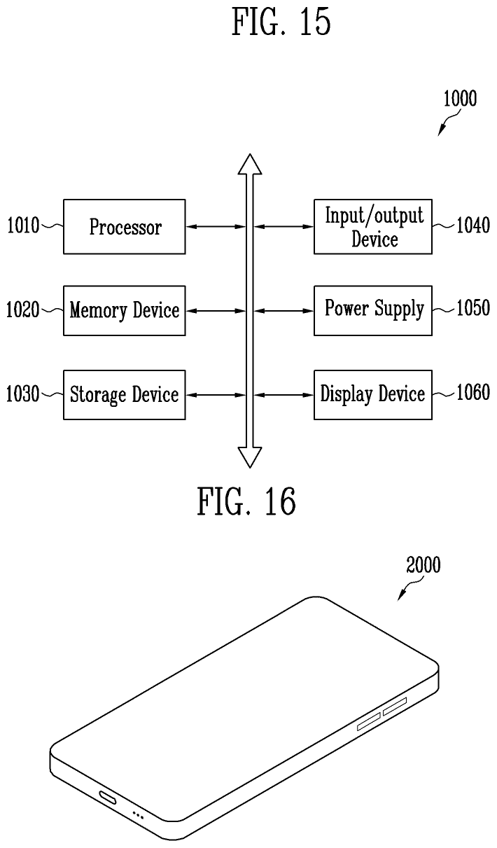

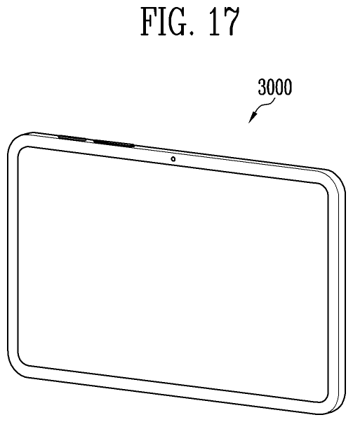

FIG. 15 is a schematic block diagram illustrating an electronic device 1000 that includes a display device in accordance with an embodiment. FIG. 16 is a schematic diagram illustrating an example where the electronic device 1000 shown in FIG. 15 is a smartphone. FIG. 17 is a schematic diagram illustrating an example where the electronic device 1000 shown in FIG. 15 is a tablet computer.

Referring to FIGS. 15 to 17, the electronic device 1000 may include a processor 1010, a memory device 1020, a storage device 1030, an input/output (I/O) device 1040, a power supply 1050, and a display device 1060. The display device 1060 may correspond to the display device DD shown in FIG. 1. The electronic device 1000 may further include various ports for communication with a video card, a sound card, a memory card, a USB device, or other systems. In an embodiment, as illustrated in FIG. 16, the electronic device 2000 may be a smartphone. In an embodiment, as illustrated in FIG. 17, the electronic device 3000 may be a tablet computer. However, the examples are illustrative, and the electronic device 1000 is not limited to the examples. For example, the electronic device 1000 may be a flat panel display, a curved display, a computer monitor, a medical monitor, a television, a billboard, an indoor light, an outdoor light, a signal light, a head-up display, a fully transparent display, a partially transparent display, a flexible display, a rollable display, a foldable display, a stretchable display, a laser printer, a telephone, a cellular phone, a video phone, a mobile phone, a smart pad, a tablet computer, a phablet, a personal digital assistant (PDA), a wearable device, a smartwatch, a navigation device for vehicles, a laptop computer, a digital camera, a camcorder, a viewfinder, a micro display, a three-dimensional (3D) display, a virtual reality display, an augmented reality display, a vehicle, a head-mounted display device, a video wall with multiple displays tiled together, a theater screen, a stadium screen, a phototherapy device, a signboard, or the like.

The processor 1010 may perform specific calculations or tasks. In an embodiment, the processor 1010 may be a microprocessor, a central processing unit, an application processor, or the like. The processor 1010 may be connected to other components through an address bus, a control bus, a data bus, and the like. In an embodiment, the processor 1010 may be connected to an expansion bus, such as a peripheral component interconnect (PCI) bus. In an embodiment, the processor 1010 may provide input image data to the display device 1060. Hence, the display device 1060 may display an image based on the input image data received from the processor 1010.

The memory device 1020 may store data required for the operation of the electronic device 1000. The memory device 1020 may function as a working memory and/or a buffer memory for the processor 1010. For example, the memory device 1020 may include one or more volatile memory devices, such as a dynamic random access memory (DRAM) device, a static random access memory (SRAM) device, and a mobile DRAM device.

The storage device 1030 may store data in response to control signals or data from the processor 1010. The storage device 1030 may include one or more non-volatile storage parts to retain data even in the case where the electronic device 1000 is powered off. In embodiments, the storage device 1030 may include a solid state drive (SSD), a hard disk drive (HDD), a CD-ROM, or the like.

The input/output (I/O) device 1040 may include input devices such as a keyboard, a keypad, a touchpad, a touch screen, or a mouse, and output devices such as a speaker or a printer. In an embodiment, the display device 1060 may be integrated with the I/O device 1040.

The power supply 1050 may supply power required for the operation of the electronic device 1000. For example, the power supply 1050 may include a power management integrated circuit (PMIC). In an embodiment, the power supply 1050 may supply power to the display device 1060.

The display device 1060 may display images in response to control signals or data from the processor 1010. The display device 1060 may be connected to other components through buses or other communication links.

In embodiments, as the channel area of the active pattern ACT has a planar structure with curved portions, current may be induced to flow in a curved shape, thereby increasing the effective channel length in the thin-film transistor TFT while maintaining a limited size. Without a separate curved portion in an edge area (or boundary) of the channel area CA, the channel area CA may include first and second portions having reduced widths, thus reducing the capacitance of the active pattern ACT. Furthermore, since the channel area CA includes a dummy portion, process variation in the channel area CA may be reduced or minimized.

Various embodiments may provide a thin-film transistor TFT with improved performance and a method of fabricating the thin-film transistor.

Various embodiments may provide a display device with enhanced performance.

The effects are not limited by the foregoing, and various other effects are anticipated.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the following claims.

What is claimed is:

1. A thin-film transistor included in a display device, comprising:
a substrate;
an active pattern disposed on the substrate, the active pattern including a first area, a second area, and a channel area between the first area and the second area;
a gate electrode disposed on the active pattern, overlapping the channel area;
a gate insulating layer disposed between the active pattern and the gate electrode;
a first electrode disposed on the gate insulating layer, connected to the first area; and
a second electrode disposed on the gate insulating layer, connected to the second area, wherein
the channel area includes a first boundary and a second boundary, which overlap side surfaces of the gate electrode and are spaced apart from each other in a first direction,
the channel area further includes a first side surface and a second side surface, spaced apart from each other in a second direction intersecting with the first direction,
the active pattern includes curved portions recessed from the first side surface and the second side surface of the channel area, respectively, in the second direction and in a direction opposite to the second direction,
the curved portions are spaced apart from each other by a first length in the first direction,
one of the curved portions is spaced apart from the first boundary by a second length in the first direction, and another of the curved portions is spaced apart from the second boundary by the second length in a direction opposite to the first direction, and
the second length is substantially equal to or greater than the first length.

2. The thin-film transistor of claim 1, wherein
the curved portions include a first curved portion recessed from the first side surface in the second direction and a second curved portion recessed from the second side surface in a direction opposite to the second direction,
the first curved portion is spaced apart from the second side surface by a third length in the direction opposite to the second direction, and
the second curved portion is spaced apart from the first side surface by the third length in the second direction.

3. The thin-film transistor of claim 2, wherein the third length is substantially equal to the first length.

4. The thin-film transistor of claim 2, wherein a length of one of the first boundary or the second boundary in the second direction is substantially equal to a sum of a length of one of the curved portions in the second direction and the third length.

5. The thin-film transistor of claim 2, wherein
the channel area includes a first portion adjacent to the first area, a second portion adjacent to the second area, and a third portion between the first portion and the second portion,
the first portion is spaced apart from the first curved portion by the first length in a direction opposite to the first direction, and the second portion is spaced apart from the second curved portion by the first length in the first direction,
the first portion and the second portion each have a first width in the second direction, and
the first width is substantially equal to the third length.

6. The thin-film transistor of claim 5, wherein the third portion partially surrounds the curved portions and has a constant width.

7. The thin-film transistor of claim 5, wherein
the first portion and the second portion are spaced apart from a first imaginary line aligned with the second direction by an identical length, and
the first imaginary line is positioned between the first curved portion and the second curved portion and is spaced apart from each of the first curved portion and the second curved portion by an identical distance.

8. The thin-film transistor of claim 5, wherein
the first portion and the second portion overlap a second imaginary line aligned with the first direction,
the third portion includes a dummy portion protruding in the second direction from an area adjacent to the second portion, and
the dummy portion, together with another part of the third portion, forms the second curved portion.

9. The thin-film transistor of claim 8, wherein
the dummy portion has a second width equal to the first length in the first direction, and
the dummy portion has a length equal to a length of each of the first curved portion and the second curved portion in the second direction.

10. The thin-film transistor of claim 2, wherein
the curved portions further include a third curved portion recessed from the first side surface in the second direction, and
the third curved portion is disposed parallel to the first curved portion, with the second curved portion positioned between the first curved portion and the third curved portion.

11. The thin-film transistor of claim 10, wherein
the channel area includes a first portion adjacent to the first area, a second portion adjacent to the second area, and a third portion between the first portion and the second portion,
the first portion is spaced apart from the first curved portion by the first length in a direction opposite to the first direction, and the second portion is spaced apart from the third curved portion by the first length in the first direction,
the first portion and the second portion each have a first width in the second direction, and
the first width is equal to the third length.

12. The thin-film transistor of claim 11, wherein the third portion partially surrounds the curved portions and has a constant width.

13. The thin-film transistor of claim 11, wherein
the first portion and the second portion are spaced apart from a first imaginary line aligned with the second direction by an identical length, and
the first imaginary line is positioned between the first curved portion and the third curved portion and is spaced apart from each of the first curved portion and the third curved portion by an identical distance.

14. The thin-film transistor of claim 13, wherein
the third portion includes a dummy portion protruding in a direction opposite to the second direction from an area adjacent to the second portion, and
the dummy portion, together with another part of the third portion, forms the third curved portion.

15. The thin-film transistor of claim 1, wherein
in case that the second length is greater than the first length, each of the curved portions has a third width in the first direction, and
in case that the first length and the second length are equal to each other, each of the curved portions has a fourth width greater than the third width in the first direction.

16. The thin-film transistor of claim 1, further comprising:
a plurality of insulating layers on the gate electrode, wherein
the first electrode and the second electrode are disposed in a same layer on the insulating layers.

17. A display device, comprising:
a display element; and
a thin-film transistor that provides a driving signal to the display element, wherein
the thin-film transistor comprises:
a substrate;
an active pattern disposed on the substrate, the active pattern including a first area, a second area, and a channel area between the first area and the second area;
a gate electrode disposed on the active pattern, overlapping the channel area;
a gate insulating layer disposed between the active pattern and the gate electrode;
a first electrode disposed on the gate insulating layer, connected to the first area; and
a second electrode disposed on the gate insulating layer, connected to the second area, wherein
the channel area includes a first boundary and a second boundary, that overlap side surfaces of the gate electrode and are spaced apart from each other in a first direction,
the channel area further includes a first side surface and a second side surface, spaced apart from each other in a second direction intersecting with the first direction,
the active pattern includes curved portions recessed from the first side surface and the second side surface of the channel area, respectively, in the second direction and in a direction opposite to the second direction,
the curved portions are spaced apart from each other by a first length in the first direction,
one of the curved portions is spaced apart from the first boundary by a second length in the first direction, and another of the curved portions is spaced apart from the second boundary by the second length in a direction opposite to the first direction, and
the second length is equal to or greater than the first length.

18. An electronic device, comprising:
a processor that provides input image data; and
a display device that displays an image based on the input image data, the display device including a display element and a thin-film transistor that provides a driving signal to the display element, wherein
the thin-film transistor comprises:
a substrate;
an active pattern disposed on the substrate, the active pattern including a first area, a second area, and a channel area between the first area and the second area;
a gate electrode disposed on the active pattern, overlapping the channel area;
a gate insulating layer disposed between the active pattern and the gate electrode;
a first electrode disposed on the gate insulating layer, connected to the first area; and
a second electrode disposed on the gate insulating layer, connected to the second area, wherein
the channel area includes a first boundary and a second boundary, that overlap side surfaces of the gate electrode and are spaced apart from each other in a first direction,
the channel area further includes a first side surface and a second side surface, spaced apart from each other in a second direction intersecting with the first direction,
the active pattern includes curved portions recessed from the first side surface and the second side surface of the channel area, respectively, in the second direction and in a direction opposite to the second direction,
the curved portions are spaced apart from each other by a first length in the first direction,
one of the curved portions is spaced apart from the first boundary by a second length in the first direction, and another of the curved portions is spaced apart from the second boundary by the second length in a direction opposite to the first direction, and
the second length is equal to or greater than the first length.

19. The electronic device of claim 18, which is at least one of a flat panel display, a curved display, a computer monitor, a medical monitor, a television, a billboard, an indoor light, an outdoor light, a signal light, a head-up display, a fully transparent display, a partially transparent display, a flexible display, a rollable display, a foldable display, a stretchable display, a laser printer, a telephone, a cellular phone, a video phone, a mobile phone, a smart pad, a tablet computer, a phablet, a personal digital assistant (PDA), a wearable device, a smartwatch, a navigation device for vehicles, a laptop computer, a digital camera, a camcorder, a viewfinder, a micro display, a three-dimensional (3D) display, a virtual reality display, an augmented reality display, a vehicle, a head-mounted display device, a video wall with multiple displays tiled together, a theater screen, a stadium screen, a phototherapy device, or a signboard.
